(19) United States
(12) Patent Application Publication
(10) Pub. No.: US 2010/0132775 A1
(43) Pub. Date: Jun. 3, 2010

(54) ADHESION BETWEEN AZO AND AG FOR THE BACK CONTACT IN TANDEM JUNCTION CELL BY METAL ALLOY

(75) Inventors: Hienminh H. Le, San Jose, CA (US); David Tanner, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/398,863

(22) Filed: Mar. 5, 2009

(51) Int. Cl. H01L 31/04; B05D 5/12; H01L 31/18

(52) U.S. Cl. 136/255; 427/74; 427/75; 136/256; 438/72; 257/E21.295; 257/E31.127

(57) ABSTRACT

Methods of promoting adhesion between a reflective backing layer and a solar cell substrate are provided. The reflective backing layer is formed over a conductive metal oxide layer as an alloy using reflective and adhesive components, the adhesive components being present in levels generally below about 5 atomic percent. Techniques are disclosed for depositing varying the concentration of the reflective backing layer to localize the adhesive components in an adhesion region near the conductive metal oxide layer. Techniques are also disclosed for boosting bonding species in the conductive metal oxide layer to further enhance adhesion.

### FIELD

Embodiments of the invention relate to methods of manufacturing solar cells. More specifically, embodiments of the invention relate to methods of forming a backing or reflector layer on a solar cell substrate.

### BACKGROUND

Solar cells are made of layers of materials that liberate electrons when light strikes them. Construction of the solar cell focuses on gathering the electrons to one locality of the cell, and the remaining positively charged “holes” to another locality, thus maintaining charge separation. The energy that originally separated the charges may then be released by sending the electrons through a circuit to do useful work.

Semiconductor materials are commonly used to form the various light-active layers of a solar cell. In a thin-film solar cell, the energy transforming part of the cell is usually referred to as a p-i-n junction. The p-i-n junction comprises three layers of a semiconductor material, one positively doped, one negatively doped, and one undoped or “intrinsic”. The intrinsic layer is between the positive and negative layers so that positive and negative charges separated in the intrinsic layer migrate in opposite directions. The doped “charge collection” layers ensure the charges separated in the “charge separation” layer do not recombine before their energy can be captured.

The separated and collected charges must be routed through an electrical circuit to take advantage of the energy captured by separating them. For this, a conductor of some kind is needed to channel the charges out of the solar cell to the load circuit. In thin-film solar cells, the conductor is frequently a layer of conductive material formed over the p-i-n junction. In many thin-film solar cells, the conductive layer is frequently a metal-oxide layer thin enough to be transparent.

Efficiency is the key parameter that makes solar cells viable as an energy generation solution. Increased efficiency is a key goal of manufacturers seeking to expand the market for solar cells and panels. One recent innovation that resulted in significant improvement in efficiency was implementation of backing layers to capture and/or reflect light that passed through the p-i-n junction without causing charge separation. The backing layers are frequently metal, and when formed over the conductive layer may adhere to the conductive layer only weakly. It is a current challenge to find a backing layer that combines reflectivity and adhesion stability for an efficient solar cell design.

### SUMMARY

Embodiments of the invention provide a method of forming a reflective layer in a solar cell, comprising forming an adhesion alloy layer on a solar cell substrate comprising a p-i-n junction, and forming a metal oxide conductor layer between the p-i-n junction and the adhesion alloy layer.

Other embodiments provide a method of forming a solar cell, comprising forming one or more p-i-n junctions on a substrate, forming a conductive metal oxide layer over the one or more p-i-n junctions, and forming a metal backing layer having one or more adhesive alloy components over the layer.

Still other embodiments provide a solar cell device, comprising one or more p-i-n junctions, one or more metal backing layers, each metal backing layer comprising one or more adhesive alloy components, and a conductive metal oxide layer between the p-i-n junction and the one or more metal backing layers.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic side view of a solar cell device according to one embodiment.

FIG. 2 is a schematic side view of a solar cell device according to another embodiment.

FIG. 3 is a flow diagram summarizing a method according to one embodiment.

FIG. 4 is a flow diagram summarizing a method according to another embodiment.

FIG. 5 is a flow diagram summarizing a method according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention generally provide methods for forming a metal backing layer on a solar cell substrate. The metal backing layer is generally formed on a solar cell substrate comprising at least one p-i-n junction, with a conductive metal oxide layer between one of the p-i-n junctions and the metal backing layer. In some embodiments, the metal backing layer is a reflector to capture light passing through the solar cell and reflect it back through the cell. Embodiments of the invention provide metal backing layers having good adhesion to the solar cell substrate. Some embodiments provide good adhesion between the metal backing layer and the conductive metal oxide layer. Other embodiments provide one or more adhesion layers between the metal backing layer and the solar cell substrate. Other embodiments provide one or more adhesion layers between the metal backing layer and the conductive metal oxide layer.

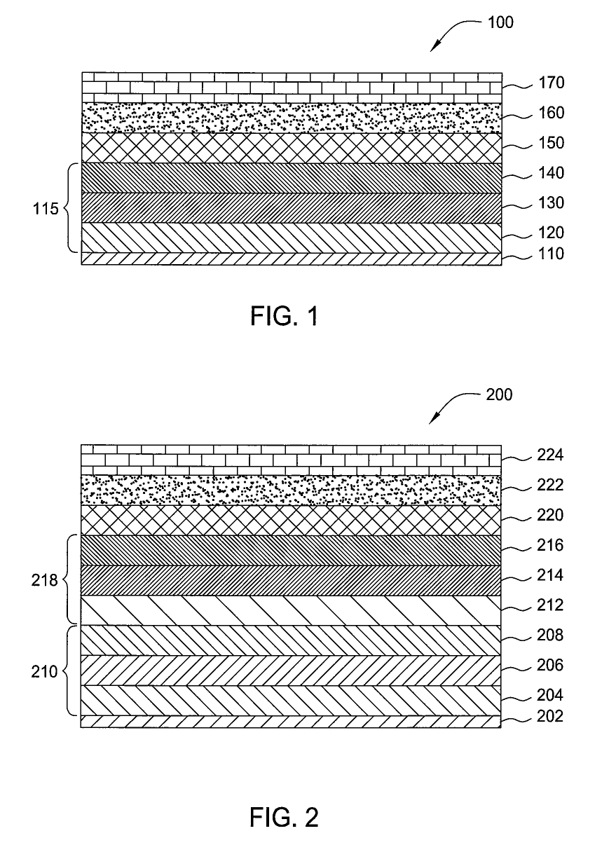

FIG. 1 is a schematic side view of a device 100 according to one embodiment of the invention. The device of FIG. 1 is a thin-film solar cell having a single p-i-n junction 115. The p-i-n junction 115 is formed on a substrate 110, which may be glass or plastic, and comprises an p-type doped semiconductor layer 120, such as a p-type doped silicon layer, an intrinsic semiconductor layer 130, such as a silicon layer, and an n-type doped semiconductor layer 140, such as an n-type doped silicon layer.

A conductive layer 150 is formed adjacent to the p-i-n junction 115, and a backing layer 160 is formed adjacent to the conductive layer 150, such that the conductive layer 150 is between the p-i-n junction 115 and the backing layer 160. The conductive layer is generally a metal oxide layer, such as a zinc oxide layer, or an aluminum-doped zinc oxide layer. A protective layer 170 is generally formed adjacent to the backing layer 160 to prevent any physical or chemical damage.

The backing layer 160 is generally metal, and may be a reflective layer. In some embodiments, the backing layer 160 is an essentially pure metal, while in others it is an alloy or a mixture. In some embodiments, the backing layer 160 comprises one or more adhesive alloy components that promote adhesion of the backing layer 160 to the conductive metal oxide layer 150. In some embodiments, the backing layer 160 is a metal layer comprising one or more dopants selected from the group consisting of silicon, aluminum, tantalum, chromium, oxygen, nitrogen, and carbon. Dopants may be provided as a gas in a reactive sputtering process, or they may be provided in the sputtering target and deposited onto the substrate along with the metal in a non-reactive sputtering process. Dopants will generally be present in the backing layer 160 at an average atomic concentration of less than about 5%, such as between about 0.5% and about 5.0%, or between about 0.5% and about 3.0%. Oxygen and nitrogen may be provided as a gas during the sputtering process in a concentration of less than about 5% by volume of total gas provided, such as between about 0.5% and about 5.0% by volume. Dopants that may be used for improving adhesion are those elements that generally form strong bonds with oxygen or with metals. Not wishing to be bound by theory, it is believed that the dopants bond with, or strongly attract, oxygen or metals in the conductive metal oxide layer, resulting in strong adhesion.

In one embodiment, the backing layer 160 comprises an alloy of silver and silicon, with the atomic concentration of silicon in the backing layer 160 ranging between about 0.5% and about 3.0%, such as between about 0.5% and about 2.0%, for example about 1.5%. The inherent reflectivity of silicon supports the reflectivity of the alloy with silver within the concentration range indicated above. In some embodiments, the backing layer 160 may be a silicon-doped silver layer.

In another embodiment, the backing layer 160 comprises an oxygen-doped silver layer or a nitrogen-doped silver layer. The oxygen or nitrogen may be incorporated by providing oxygen or nitrogen gas with the sputtering gas during the sputtering deposition process. For example, oxygen gas may be provided in a ratio ranging between about 0.5% to 5.0% by volume to argon gas in a sputtering process. A portion of the oxygen is included in the deposited layer, and is strongly attracted to metals in the conductive layer to promote adhesion.

In another embodiment, the backing layer 160 may be an alloy of silver with two or more adhesion components selected from the group consisting of silicon, aluminum, tantalum, titanium, nickel, chromium, oxygen, nitrogen, and carbon. For example, the backing layer may be sputtered from a target comprising silver and two other metals such as aluminum and tantalum. Alternately, targets having essentially pure components may be sputtered simultaneously to deposit an alloy layer.

In some embodiments, the backing layer 160 may have varying composition. For example, the backing layer 160 may comprise a plurality of layers having different composition. In one embodiment, the backing layer 160 may comprise a first layer and a second layer, the first layer comprising a metal alloyed with adhesive components, and the second layer comprising only reflective metals. The first layer may be formed adjacent to the conductive layer 150 to promote adhesion, while the second layer, formed on the first layer, is reflective. In other embodiments, the backing layer 160 may be an alloy of a metal with adhesion alloy components, the concentration of which is graded. For example, the backing layer 160 may comprise an alloy of metal and an adhesion component, wherein the concentration of the adhesion component varies from a first concentration near the conductive layer 150 to a second concentration at the opposite surface from the conductive layer 150. The concentration of the adhesion component may vary smoothly from the first concentration to the second concentration, such as in a linear, quasi-linear, or sigmoidal fashion, or the concentration may vary in a stepwise fashion, progressing through intermediate concentrations between the first concentration and the second concentration. The backing layer may thus comprise a plurality of layers, each varying slightly in composition from those immediately adjacent to it by virtue of different concentrations of adhesive alloy components.

The first concentration near the conductive layer 150 will generally be between about 2.5% and about 3.5%, and the second concentration will generally be less than about 0.5% near the surface opposite the conductive layer 150. The metal component of the alloy may be silver, or a blend of silver with one or more metals such as aluminum, tantalum, titanium, nickel, and chromium. The adhesion component of the alloy may be a non-metal, such as oxygen, nitrogen, silicon, carbon, or a mixture thereof, or it may be one or more metals such as aluminum, tantalum, titanium, nickel, or chromium. In other embodiments, a thin first layer with graded composition may be deposited near the conductive layer 150, and a second layer having uniform composition may be deposited over the thin first layer. In still other embodiments, multiple layers may be deposited sequentially having different compositions. In one embodiment, a plurality of layers may be deposited each having adhesive alloy components, wherein the concentration of adhesive alloy components in each layer is less than that in the layer deposited immediately before. In still other embodiments, a backing layer having an adhesion region and a reflection region may be formed on the solar cell substrate.

In some embodiments, components of the backing layer 160 may mix with components of the conductive layer 150 to form a bonding layer at the interface between the backing layer 160 and the conductive layer 150. Adhesion components in the backing layer 160 may diffuse into the surface of the conductive layer 150 leading to a mixed composition of elements from the conductive layer 150 and the backing layer 160 in a thin bonding layer. Such a bonding layer may have thickness of between about 5 Å and about 50 Å. In some embodiments, the conductive layer 150 may have a specially prepared bonding surface that contributes components such as oxygen or nitrogen to the bonding layer. The protective layer 170 formed adjacent to the backing layer 160 is generally a hard metal alloy, such as nickel-vanadium alloy.

The conductive layer 150 will generally be less than about 1,000 Å thick, such as between about 500 Å and about 1,000 Å thick, for example about 900 Å thick. The backing layer 160 may have a thickness that ranges between about 1,000 Å and about 3,000 Å, such as about 2,000 Å. The protective layer 170 will generally have a thickness of about 500 Å or less. In embodiments wherein the backing layer 160 is a bilayer comprising a first adhesive layer and a second reflective layer, the first adhesive layer will generally be thin, having a thickness of about 200 Å or less, and the second reflective layer will range in thickness from about 800 Å to about 2,800 Å. In embodiments wherein the backing layer 160 comprises a plurality of layers, the overall thickness of the backing layer 160 will generally have the same range.

FIG. 2 is a schematic side view of a solar cell device 200 according to another embodiment of the invention. The device 200 of FIG. 2 is a tandem-junction thin-film solar cell device having a first p-i-n junction 210 formed adjacent to a substrate 202, and a second p-i-n junction 218 formed adjacent to the first p-i-n junction 210. Each of the p-i-n junctions 210 and 218 comprises a p-type layer 204 and 212, an intrinsic-type layer 206 and 214, and an n-type layer 208 and 216. In some embodiments, the p-i-n junctions 210 and 218 may be separated by a buffer layer (not shown). A conductive layer 220 is generally formed adjacent to the n-type layer 216 of the second p-i-n junction 218. In some embodiments, a degeneratively doped p-type layer (not shown) may be formed between the second p-type layer 212 and the conductive layer 220. In some embodiments, the n-type layer 216 or the degeneratively doped p-type layer may be passivated by forming a thin nitrogen-containing layer (not shown) thereon. In most embodiments, the conductive layer 220 is formed as a metal oxide layer, such as a transparent conductive oxide (TCO) layer. In some embodiments, the conductive layer is a zinc oxide layer or an aluminum-doped zinc oxide layer. The conductive layer may be formed using a CVD or PVD process, which may be plasma enhanced, as described in further detail below.

A backing layer 222 is formed adjacent to the conductive layer 220. The backing layer 222 is generally reflective to facilitate capturing light that passes through the solar cell without activating electrons. The backing layer 222 will generally comprise a reflective material, such as a metal, and may be an essentially pure metal or an alloy. In most respects, the backing layer 222 will be similar to the backing layer 160 of FIG. 1, described above. As described in conjunction with FIG. 1 above, the backing layer 222 and the conductive layer 220 may form a thin bonding layer. A protective layer 224 similar to that described above is formed adjacent to the backing layer 222.

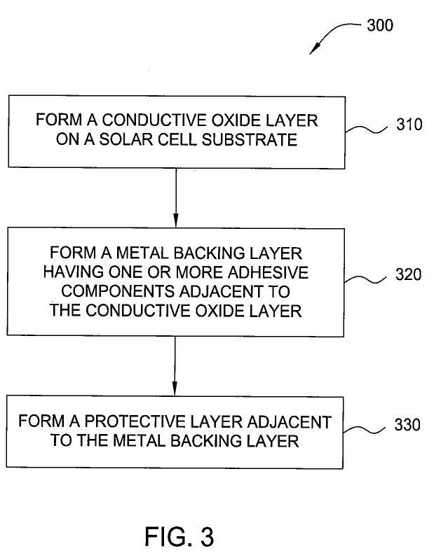

FIG. 3 is a flow diagram summarizing a method 300 according to one embodiment. The method 300 is generally useful for making embodiments of the backing layers 160 and 222 described in reference to FIGS. 1 and 2. At 310, a conductive oxide layer is formed on a solar cell substrate. The conductive oxide layer may comprise a metal oxide, such as zinc oxide or aluminum-doped zinc oxide, and may be formed by a chemical or physical vapor deposition process known to the art, which may be plasma enhanced. The conductive oxide layer may be formed to a thickness generally less than about 100 nm.

A metal backing layer is formed over the conductive layer at 320. The metal backing layer will generally be an alloy comprising one or more reflective components and one or more adhesive components. In most embodiments, the reflective component is silver, but in some embodiments, chromium or nickel may be included in small proportions. The adhesive components generally selected for their attraction to oxygen or metal in the conductive layer. In some embodiments, the adhesive components are selected from the group consisting of aluminum, tantalum, titanium, nickel, chromium, silicon, oxygen, nitrogen, and combinations thereof. The adhesive component will generally be present in an atomic concentration between about 0.5% and about 5.0%, such as between about 0.5% and about 3.0%, for example between about 1.5% and about 2.5%. In one embodiment, the metal backing layer comprises silver and silicon, with an atomic concentration of silicon between about 0.5% and about 3.0%.

The metal backing layer formed at 320 may be advantageously formed by a sputtering process. A solar cell substrate to be treated is disposed in a chamber having a substrate support and one or more electrodes for generating an electric field. A sputtering target comprising material to be deposited on the substrate is disposed in the chamber, and is frequently located between an electrode and the substrate support. The member has a magnetic component that facilitates the sputtering process by attracting ions to collide with the target, dislodging material that falls on the substrate. In some embodiments, more than one target is disposed in the chamber. A sputtering gas such as argon is provided to the sputtering chamber, and an electric field applied to ionize the sputtering gas. The electric field may be generated by disposing an electrode above the sputtering target, and powering the electrode, and optionally the target, with DC power, RF power, or both, to generate an electrical bias between the electrode and the target. Ions from the sputtering gas are attracted to the target by the magnetic field, collide with the target, and dislodge material from the target. The dislodged material rains down upon the substrate disposed below to form a film. In many embodiments, the substrate is coated with material while passing under the targets being sputtered.

In an exemplary embodiment, a doped silver sputtering target is used to form a reflective layer on a solar cell substrate. The doped silver target may be an alloy of silver and one or more adhesion components selected from the group consisting of aluminum, tantalum, titanium, nickel, chromium, silicon, oxygen, nitrogen, carbon, and combinations thereof. The one or more adhesion components will generally be present in an atomic concentration between about 0.5% and about 5.0%, such as between about 0.5% and about 3.0%, for example between about 1.5% and about 2.5%. A substrate to be processed is disposed on a substrate support in the chamber containing the doped silver target. A gas is supplied to the chamber, and an electric field of strength between about 1,000 V and about 5,000 V is applied to the gas. The electric field may be generated by applying alternating or direct voltage to one or more electrodes in the chamber, which may include the target and the substrate support. In an exemplary embodiment, the target is disposed between a plate electrode and the substrate support, and power applied to the plate electrode and the target. Alternating voltage may be applied as RF power ranging in frequency from about 10 kHz to about 13.56 MHz, with power between about 1,000 W and about 5,000 W being applied to the target. The electric field ionizes the gas, producing a plasma in some embodiments. Magnets disposed in or near the target, for example in a magnetron, enhance sputtering of the target by the ions. Argon or helium is generally used as the sputtering gas for a non-reactive process, and either may be provided at a flow rate between about 1,000 sccm and about 5,000 sccm, with the chamber pressure maintained between about 1 mTorr and about 1 Torr. In this way, a reflective backing layer having homogeneous composition and good adhesion to the solar cell substrate may be formed to a thickness between about 100 nm and about 300 nm, such as about 200 nm.

In an alternate embodiment, oxygen may be used as the adhesion component for the backing layer, the oxygen being used to bond with metals in the substrate. A silver sputtering target may be used for the reflective component, and oxygen gas supplied with the argon or helium gas to perform a reactive sputtering process. The oxygen gas may be supplied in a ratio of between about 0.5% and about 5.0% by volume to the argon or helium gas, and some of the oxygen may be ionized by the electric field. Oxygen reacts with a fraction of the silver dislodged from the target, resulting in a layer of silver with atomic oxygen content between about 0.5% and about 3.0%. In other embodiments, nitrogen may be used with, or in place of, oxygen to similar effect. In still other embodiments, oxygen and/or nitrogen may be used along with other adhesion components described herein to bond the backing layer to the substrate.

In another alternate embodiment, more than one sputtering target may be provided. For example, a first target may be an essentially pure reflective component, such as silver, while a second target provides an adhesion component such as silicon or chromium. The second target may provide a mixture of adhesion components in some embodiments. Concentration of the adhesion component in the deposited layer may be controlled by adjusting the power level applied to the second target in relation to the first target. The ratio of the two power levels and the liberation energy of the two target materials will determine the concentration of the components in the deposited layer. Thus, sputtering energy may be applied to the first target at a first power level, and to the second target at a second power level, wherein a ratio of the two power levels is selected to deposit a layer having the target composition. In embodiments wherein material from two targets differing in composition is simultaneously sputtered onto a stationary substrate, compositional uniformity of the deposited film is enhanced if the targets are physically close together relative to the distance between the targets and the substrate. For example, if two cylindrical targets are used, the center-to-center distance between the two targets may be less than about 10% of the distance between the centers of the two targets and the substrate surface to promote compositional uniformity of the deposited layer.

In other embodiments, the targets may be different mixtures of reflective and adhesive components. A first target may be provided that has a high concentration of adhesive components relative to the reflective components, while a second target has a low concentration of adhesive components. For example, the first target may have a first atomic concentration of adhesive components, and the second target a second atomic concentration, wherein the first concentration is up to 10 times the second concentration. In one embodiment, the first concentration may be between about 10% and about 30% while the second concentration is between about 1% and about 3%. Such compositional relationships between sputtering targets may be used to target detailed compositional features such as gradients, inflections, or discontinuities, in the deposited film.

In an exemplary embodiment, a silver target and a silicon target may be separately and simultaneously sputtered in a sputtering chamber to deposit a reflective layer having good adhesion properties. In one embodiment, a substrate to be processed is disposed on a stationary substrate support in a chamber having the two sputtering targets, and a sputtering gas is provided to the chamber. The sputtering gas may be argon or helium. If argon is used, RF power is applied to each of the two targets and to one or more electrodes disposed in the chamber above the targets. Each target may have a corresponding electrode, or one electrode may overspread the two targets. In order to deposit a layer having between about 0.5% and about 3.0% silicon, the power level of RF power applied to the silicon target may be between about 1% and about 5% of the power level applied to the silver target. In one exemplary embodiment, RF power may be applied to the silver target at a power level of about 5 kW while RF power is applied to the silicon target at a power level between about 50 W and about 250 W. In an alternate embodiment, the substrate may be disposed on a moving support that passes the substrate beneath the targets as power is applied. The speed the substrate is moved beneath the targets is selected to deposit a film having the desired thickness.

A protective layer is formed over the metal backing layer at 330. The protective layer is generally selected to provide protection from mechanical and chemical degradation caused by environmental factors. In one embodiment, a layer comprising nickel and vanadium is deposited to a thickness of 50 nm or less by sputtering one or more nickel-vanadium alloy targets, or by sputtering one or more targets comprising essentially pure nickel or essentially pure vanadium simultaneously.

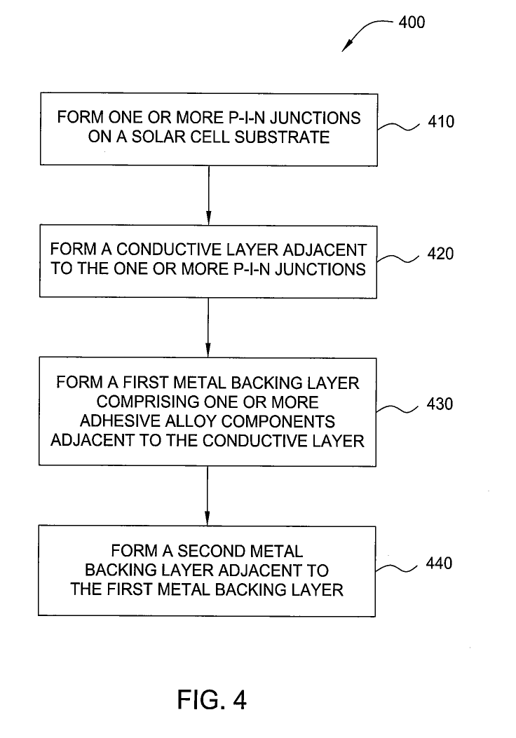

FIG. 4 is a flow diagram summarizing a method 400 according to another embodiment of the invention. One or more p-i-n junctions are formed on a solar cell substrate at 410. A conductive layer is formed over the one or more p-i-n junctions at 420. The conductive layer generally comprises an oxide layer, for example a metal oxide layer such as zinc oxide or aluminum-doped zinc oxide, and is formed by a CVD or PVD process, either of which may be plasma enhanced.

In a CVD process, a substrate is disposed on a substrate support in a processing chamber, and one or more process gases supplied to the chamber. One gas mixture may be supplied, or multiple gases or gas mixtures may be supplied to the chamber. The substrate is maintained at a temperature that encourages the gases to react at the substrate surface to form the desired film. To form a metal oxide film, a metal source and an oxygen source are provided, either as separate gases or in a gas mixture, and react with proximity to the substrate surface. Metal precursors are frequently organometallic compounds, and oxygen precursors are usually simply oxygen-containing gases such as oxygen gas, ozone, nitrous oxide, carbon monoxide, or carbon dioxide. To form a zinc oxide conductive film by CVD, an organozinc compound such as dimethyl zinc or diethyl zinc may be provided to the chamber with any of the oxygen sources mentioned above. A carrier gas may also be provided to facilitate mixing and pressure control. The zinc precursor and oxygen precursors are generally provided in approximate molar equivalence to form a film having approximate stoichiometry of zinc oxide.

In a PVD process, a zinc oxide or aluminum-doped zinc oxide target may be sputtered onto a substrate disposed on a substrate support beneath the target by processes similar to those described herein. In some embodiments, a PVD process to form an aluminum-doped zinc oxide layer may be followed immediately by a PVD process to form a reflective backing layer by positioning two or more chambers together with a moving substrate support to carry substrates to the chamber sequentially.

In one embodiment, adhesion of a reflective backing layer to a conductive film on a solar cell substrate may be improved by increasing a concentration of bonding components in the conductive film near the interface with the reflective backing layer prior to forming the reflective backing layer. Increasing the bonding components near the surface of the conductive layer provides more bonding sites for adhesive components in the reflective layer, improving overall adhesion of the reflective layer. The excess bonding components may also diffuse into the reflective layer to a greater extent, increasing the thickness of the bonding layer at the interface between the conductive layer and the reflective layer.

For example, if the bonding component in the conductive oxide layer is to be oxygen, the concentration of oxygen may be increased near the surface of the conductive oxide layer by adjusting deposition chemistry near the end of the deposition process, or by performing an oxygen treatment after forming the conductive layer. In a PVD embodiment, a metal oxide layer may be deposited from a metal oxide target using a standard non-reactive sputtering process with argon as the sputtering gas. Oxygen gas or ozone may be provided with the argon gas for the last few seconds of the sputtering process to boost the oxygen content near the surface of the conductive layer. For example, in a non-reactive sputtering process wherein argon is provided at a flow rate between about 1,000 sccm and 5,000 sccm and RF power is applied to a metal oxide target for 100 seconds over a stationary substrate, oxygen gas may be provided to the chamber at a flowrate about 3,000 sccm or less during the last 10 seconds of the sputtering process to increase the oxygen content at the surface. In a PVD process featuring a moving substrate, the substrate may be moved into a chamber performing a non-reactive sputtering process as described above, followed by a chamber performing a reactive sputtering process in which oxygen is added to the sputtering gas. In a CVD embodiment, the proportion of the oxygen precursor may be increased by increasing concentration of the oxygen source in the precursor gas near the end of the deposition process. If the precursors are provided in approximate molar equivalence, it may be useful to boost the concentration of the oxygen precursor by up to about 20% to deposit more oxygen into the surface of the film. For example, if an organozinc precursor and an oxygen precursor are each provided to the processing chamber at a rate of 0.5 mmol/min, the rate of the oxygen precursor may be boosted to 0.6 mmol/min for a desired time to boost the amount of oxygen included in the film surface.

Alternately, oxygen may be added to the conductive film surface following deposition by exposing the deposited film to an oxygen containing gas or plasma. When exposing the film to an oxygen plasma, incorporation of oxygen ions may be further enhanced by applying an electrical bias to the substrate. Any well-known ion implant process may be used with oxygen gas or ozone, but nitrous oxide may also be used for embodiments in which nitrogen is a useful bonding component.

At 430, a first metal backing layer is formed over the conductive layer. The first metal backing layer comprises one or more adhesive alloy components and one or more reflective components. The first metal backing layer is generally formed by a PVD process in which one or more targets comprising the material to be deposited is sputtered by a sputtering gas subjected to an electric field. A single target having the composition of the layer to be deposited may be used, or multiple targets may be sputtered simultaneously. In a multiple-target embodiment, the targets may have compositions that are substantially the same, each having composition similar to the layer being formed, or they may have different compositions with one subset having mainly reflective components and another having more adhesive components. The reflective components generally comprise silver, but may comprise other reflective metals such as chromium or nickel. The adhesive components may comprise one or more materials selected from the group consisting of aluminum, tantalum, titanium, nickel, chromium, silicon, oxygen, nitrogen, and carbon.

At 440, a second metal backing layer is formed over the first metal backing layer. The second metal backing layer will generally comprise reflective components with little or no adhesive component. The adhesive component added to the first metal layer serves to adhere the entire metal backing bi-layer to the conductive layer. The transition from the first to the second metal backing layer may be accomplished by using a sputtering process wherein at least a first target and a second target are sputtered. The first target comprises reflective components, while the second target comprises adhesive components. To form the first metal backing layer, the first and second targets are sputtered simultaneously, with the power applied to each target adjusted independently to adjust the composition of the deposited layer. In an embodiment wherein the substrate is stationary, the second metal backing layer is deposited by interrupting the power to the second target while power to the first target is maintained.

Not wishing to be bound by theory, it is thought that the adhesive components deposited near the interface between the metal backing layer or bi-layer and the conductive layer, bond with, or strongly attract, oxygen or metals in the conductive layer to promote adhesion. The adhesive components disposed in the metal backing layer form a bonding layer at the interface with the conductive layer. Some adhesive components bond, or partially bond, to oxygen or metals in the conductive layer. Some adhesive components may also diffuse into the conductive layer to form a bonding layer comprising materials from the deposited film and materials from the conductive layer in a bonding alloy.

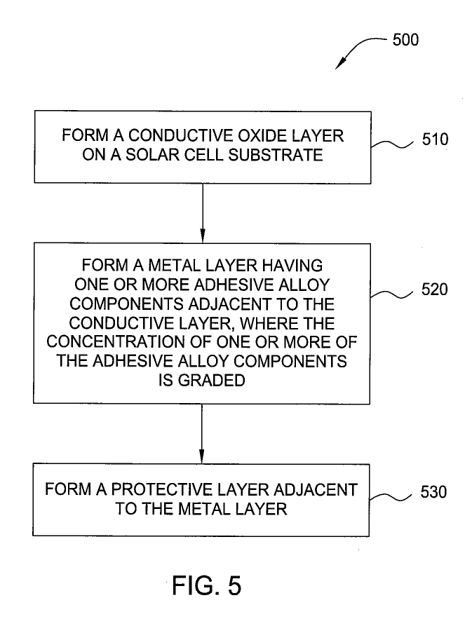

FIG. 5 is a flow diagram summarizing a method 500 according to an embodiment. A conductive oxide layer is formed on a solar cell substrate at 510. At 520, a metal layer having one or more adhesive components is formed adjacent to the conductive oxide layer. In some embodiments, the metal backing layer is an adhesion alloy layer with a graded composition of reflective and adhesive components formed adjacent to the conductive metal oxide layer. The composition of the adhesion alloy layer is graded from a first composition at a first surface near the interface of the adhesion alloy layer with the conductive metal oxide layer to a second composition at a second surface opposite the conductive metal oxide layer. The first composition is generally relatively rich in adhesive components, such as between about 2 atomic percent and about 4 atomic percent, while the second composition is relatively poor in adhesive components, such as less than about 0.5 atomic percent. In some embodiments, adhesive components may be entirely absent at the second surface. A layer with graded composition couples good adhesion to the underlying conductive metal oxide layer with maximum reflective properties, while avoiding compositional discontinuities that may be undesirable in some embodiments. A protective layer is formed adjacent to the metal layer at 530.

A backing layer of this sort may be formed by sputtering two targets of differing composition simultaneously over a moving substrate. In one embodiment, a substrate may be disposed on a carrier configured to move the substrate through a processing chamber having the two sputtering targets, the first having only adhesive components, such as silicon, and the second having only reflective components, such as silver, disposed along the direction of motion of the carrier. The first target is disposed such that the substrate encounters it first, with the second target following. While both targets are sputtered simultaneously, the substrate is moved through the chamber beneath the first target, and then the second target. As the substrate moves beneath the first target, the deposited layer is higher in adhesive content, and as the substrate moves beneath the second target, reflective content of the deposited film rises. The deposited film thus has a graded composition, which may be linear, quasi-linear, or sigmoidal, monotonically increasing in amount of reflective components from the first surface to the second surface. The first concentration of adhesive components in the backing layer can be influenced by the relative power levels applied to the two targets. If a first power level is applied to the first target, and a second power level is applied to the second target, the first concentration will vary in a direct linear relationship to the ratio of the first power level to the second power level for a backing layer having a first concentration below about 10 atomic percent.

In an alternate embodiment, a metal backing layer may be formed that is a bi-layer having a first layer and a second layer, wherein the first layer has a graded composition and the second layer is substantially homogeneous. The first layer will generally be an adhesive alloy layer, and may be formed as described above. The substrate on the carrier may then be moved beneath a second target having only reflective components to form a second layer that is substantially homogeneous in reflective components. The bi-layer thus formed has a discontinuous composition profile, with adhesive components localized to an adhesion region near the interface between the metal backing layer and the conductive layer.

### EXAMPLES

Back contacts were formed on the AZO layer of a series of thin film solar cells, according to the conditions set forth in Table 1. In half the samples, a silver backing layer was formed on the AZO layer. In the other half, a silver layer, doped with 0.5% silicon was formed on the AZO layer. A nickel-vanadium layer was deposited over the backing layer in all cases. Properties of the resulting solar cells are set forth in Table 2.

TABLE 1
PROCESSING CONDITIONS

| Parameter | Unit | AZO | Backing | NiV |
|---|---|---|---|---|
| Conveyor Speed | m/min | 0.93 | 0.93 | 0.93 |
| Ar Total Flow | Sccm | 200-500 | 100-300 | 200-500 |
| Pressure | hPa | 2.1-2.5 × 10⁻³ | 2.2-4 × 10⁻³ | 3-3.4 × 10⁻³ |
| DC Power | kW | 35 | 22 | 25 |
| Target Voltage | V | 500-555 | 460-530 | 430-510 |
| Target Current | A | 50-80 | 30-50 | 35-70 |

TABLE 2
AZO/Ag

| Split Coupon | Avg | Min | Max | STD |
|---|---|---|---|---|
| CE (%) | 10.57 | 10.20 | 10.85 | 0.27 |
| J_{sc} (mA/cm²) | 10.70 | 10.39 | 10.88 | 0.22 |
| V_{oc} (V) | 1.36 | 1.35 | 1.38 | 0.01 |
| FF (%) | 72.66 | 72.13 | 73.39 | 0.62 |
| Rₛₕ (Ω) | 6181.65 | 4996.25 | 7832.86 | 1305.71 |
| Rₛ (Ω) | 20.72 | 19.78 | 21.49 | 0.71 |

TABLE 3
AZO/AgSi 0.5%

| Split Coupon | Avg | Min | Max | STD |
|---|---|---|---|---|
| CE (%) | 10.50 | 10.33 | 10.81 | 0.19 |
| J_{sc} (mA/cm²) | 10.76 | 10.48 | 10.93 | 0.20 |
| V_{oc} (V) | 1.35 | 1.34 | 1.37 | 0.01 |
| FF (%) | 72.13 | 71.22 | 72.80 | 0.71 |
| Rₛₕ (Ω) | 6432.04 | 4984.29 | 8317.50 | 1342.75 |
| Rₛ (Ω) | 20.40 | 20.03 | 21.07 | 0.45 |

The solar cells resulting from incorporation of silicon in the silver back reflector according to one embodiment exhibited electrical properties similar to cells with pure silver back coatings deposited directly on AZO, with significantly improved adhesion and stability and significantly reduced delamination.

While the foregoing is directed to embodiments of the invention, other and further embodiments of the invention may be devised without departing from the basic scope thereof.

What is claimed is:

1. A method of forming a reflective layer on a solar cell substrate, comprising:
forming a metal oxide conductor layer on the substrate; and
forming an adhesion alloy layer comprising reflective and adhesive components on the substrate.

2. The method of claim 1, wherein the adhesion alloy layer comprises one or more metals and one or more non-metals.

3. The method of claim 2, wherein one of the one or more metals is silver.

4. The method of claim 2, wherein one of the one or more non-metals is silicon.

5. The method of claim 1, wherein the adhesion alloy layer comprises silver doped with a reflective non-metal.

6. The method of claim 5, wherein the adhesion alloy layer has a graded composition.

7. The method of claim 5, wherein the concentration of the reflective non-metal in the adhesion alloy layer is higher near the metal oxide conductor layer.

8. The method of claim 1, wherein the adhesion alloy layer comprises silver and silicon.

9. The method of claim 2, further comprising forming a bonding layer between the metal oxide conductor layer and the adhesion alloy layer.

10. A method of forming a solar cell, comprising:
forming one or more p-i-n junctions on a substrate;
forming a conductive metal oxide layer adjacent to the one or more p-i-n junctions; and
forming a metal backing layer having one or more adhesive alloy components adjacent to the metal oxide layer.

11. The method of claim 10, wherein the metal backing layer is a reflector.

12. The method of claim 10, wherein the metal backing layer comprises one or more reflective metals and one or more reflective non-metals.

13. The method of claim 10, wherein the metal backing layer has a graded composition.

14. The method of claim 12, wherein the concentration of the one or more reflective non-metals decreases with distance from the conductive metal oxide layer.

15. The method of claim 10, wherein the metal backing layer comprises silver and silicon, and the silicon concentration varies between about 0.5 atomic percent and about 3 atomic percent.

16. The method of claim 12, further comprising forming a bonding layer between the conductive metal oxide layer and the metal backing layer.

17. The method of claim 15, wherein the metal backing layer further comprises chromium.

18. A solar cell, comprising:
a metal oxide conductor layer; and
an adhesion alloy layer adjacent to the metal oxide conductor layer, wherein the adhesion alloy layer comprises an alloy of reflective and adhesive components.

19. The solar cell of claim 18, wherein the adhesion alloy layer comprises one or more metals and one or more non-metals.

20. The solar cell of claim 18, wherein the adhesion alloy layer comprises silver and silicon.

21. The solar cell of claim 20, wherein a concentration of silicon in the adhesion alloy layer is between about 0.5 atomic percent and about 3.0 atomic percent.

22. A thin film photovoltaic device, comprising:
one or more p-i-n junctions;
a conductive metal oxide layer adjacent to the one or more p-i-n junctions;
an alloy reflector layer adjacent to the conductive metal oxide layer, wherein the alloy reflector layer comprises one or more metals and one or more non-metals; and
a protective layer formed adjacent to the alloy reflector layer.

23. The thin film photovoltaic device of claim 22, wherein the alloy reflector layer comprises silicon.

24. The thin film photovoltaic device of claim 22, wherein a concentration of the one or more non-metals in the alloy reflector layer is between about 0.5 atomic percent and about 3.0 atomic percent.

25. The thin film photovoltaic device of claim 23, wherein a concentration of silicon in the alloy reflector layer is between about 0.5 atomic percent and about 3.0 atomic percent.
